(19) United States
(12) Patent Application Publication
(10) Pub. No.: US 2011/0048491 A1
(43) Pub. Date: Mar. 3, 2011

(54) SOLAR-CELL MODULE AND SOLAR CELL

(75) Inventor: Shigeharu TAIRA, Amagasaki City (JP)

(73) Assignee: SANYO ELECTRIC CO., LTD., Moriguchi City (JP)

(21) Appl. No.: 12/858,504

(22) Filed: Aug. 18, 2010

(30) Foreign Application Priority Data
Aug. 26, 2009 (JP) 2009-196144

(51) Int. Cl. H01L 31/042; H01L 31/00; H01L 31/18

(52) U.S. Cl. 136/244; 136/252; 438/98; 257/E31.124

(57) ABSTRACT

A solar-cell module comprises a plurality of solar cells electrically connected each other by wiring materials. Each solar cell comprises: a photoelectric conversion body including a first surface irradiated with light and a second surface located on the opposite side to the first surface, the photoelectric conversion body configured to generate carriers by the irradiation of light; a plurality of finger electrodes provided on both the first surface and the second surface, and configured to collect the carriers generated by the photoelectric conversion body; and a busbar electrode provided on each of the first surface and the second surface so as to intersect the plurality of finger electrodes, and having a non-linear shape. Each of the busbar electrodes provided on the first surface and the busbar electrode formed on the second surface includes at least two markers for alignment of positions.

### CROSS REFERENCE TO RELATED APPLICATIONS

This application claims priority based on 35 USC 119 from prior Japanese Patent Application No. P2009-196144 filed on Aug. 26, 2009, entitled “SOLAR-CELL MODULE AND SOLAR CELL”, the entire contents of which are incorporated herein by reference.

### BACKGROUND OF THE INVENTION

1. Field of the Invention

The invention relates to a solar-cell module including plural solar cells that are electrically connected to one another with a wiring material and also relates to a solar cell.

2. Description of Related Art

Solar cells are capable of converting sunlight energy, which is clean and can be inexhaustibly supplied, directly into electric energy, and are therefore expected to be a new energy source.

A solar cell includes a photoelectric conversion body configured to generate carriers by receiving sunlight or the like, plural finger electrodes configured to collect the carriers generated by the photoelectric conversion body, busbar electrodes connected to the plural finger electrodes, and the like. Generally, the finger electrodes and the busbar electrodes are provided on both a front surface (light-receiving surface) and a rear surface of the photoelectric conversion body.

In addition, because a single solar-cell has an output of approximately several watts, a solar-cell module that enhances the output by connecting plural solar cells with a tab (wiring material) is used. The tab is bonded to a top of the busbar electrode with a resin adhesive.

It has been proposed to form such a solar-cell module by use of a solar cell that has a busbar electrode with a non-linear shape such as a zigzag shape to more securely connect the busbar electrode and the tab to each other (see, for example, Japanese Patent No. 4294048 (FIG. 6)). In such a solar cell, the busbar electrode, without being made wider, can be connected to the tab more securely and can achieve improved conductivity in comparison to an ordinary, linearly-shaped busbar electrode bonded to a tab with solder.

However, if busbar electrodes with non-linear shapes, such as zigzag shapes, are provided both on a front surface (light-receiving surface) of a photoelectric conversion body and on a rear surface thereof, and if the positions of the busbar electrodes printed, by screen printing or the like, on the front surface and the rear surface of the photoelectric conversion body do not coincide with each other, the following problem takes place.

Specifically, areas where the busbar electrodes exist are pressurized when the busbar electrodes and the tabs are bonded to one another. In this process, if the position of the busbar electrode on the front-surface side and the position of the busbar electrode on the rear-surface side are offset a little from each other, an unsupportable shear stress acts on the photoelectric conversion body, and damages such as cracks are likely to occur in the photoelectric conversion body. Consequently, a problem of lowering the yields of the solar cells occurs.

### SUMMARY OF THE INVENTION

An aspect of the invention provides a solar-cell module that comprises: a plurality of solar cells electrically connected each other by wiring materials, each solar cell comprising: a photoelectric conversion body including a first surface irradiated with light and a second surface located on the opposite side to the first surface, the photoelectric conversion body configured to generate carriers by the irradiation of light; a plurality of finger electrodes provided on both the first surface and the second surface, and configured to collect the carriers generated by the photoelectric conversion body; and a busbar electrode provided on each of the first surface and the second surface so as to intersect the plurality of finger electrodes, and having a non-linear shape, wherein each of the busbar electrode provided on the first surface and the busbar electrode formed on the second surface includes at least two markers for alignment of positions.

It is preferable that each of the markers is provided on a center line that passes through a center of the corresponding busbar electrode in a direction orthogonal to a direction in which the busbar electrode extends.

It is preferable that in a plan view of the photoelectric conversion body, each of the markers provided on the first surface overlaps the corresponding marker provided on the second surface.

It is preferable that each of the markers has a rectangular shape, and each of the markers has a long side extending in a direction in which each of the plurality of finger electrodes extends.

It is preferable that the markers provided on the first surface are different in shape from the markers provided on the second surface.

It is preferable that the wiring materials are bonded to tops of the busbar electrodes with a resin adhesive.

Another aspect of the invention provides a solar cell that comprises a photoelectric conversion body including a first surface irradiated with light and a second surface located on the opposite side to the first surface, the photoelectric conversion body configured to generate carriers by the irradiation of light; a plurality of finger electrodes provided on both the first surface and the second surface, and configured to collect the carriers generated by the photoelectric conversion body; and a busbar electrode provided on each of the first surface and the second surface so as to intersect the plurality of finger electrodes, and having a non-linear shape, wherein each of the busbar electrodes provided on the first surface and the busbar electrode formed on the second surface includes at least two markers for alignment of positions.

Still another aspect of the invention provides a method of solar cell that comprises: forming a photoelectric conversion body including a first surface irradiated with light and a second surface located on the opposite side to the first surface, the photoelectric conversion body configured to generate carriers by the irradiation of light; forming a plurality of finger electrodes provided on both the first surface and the second surface, and configured to collect the carriers generated by the photoelectric conversion body; and forming a busbar electrode provided on each of the first surface and the second surface so as to intersect the plurality of finger electrodes, and having a non-linear shape, wherein each of the busbar electrodes provided on the first surface and the busbar electrode formed on the second surface includes at least two markers for alignment of positions.

### BRIEF DESCRIPTION CF THE DRAWINGS

FIG. 1 is a schematic perspective view of a solar-cell module according to an embodiment.

FIG. 2 is a plan view of light-receiving surface S1 of solar cell 100A according to the embodiment.

FIG. 3 is a plan view of rear surface S2 of solar cell 100A according to the embodiment.

FIG. 4 is a sectional view of a part of solar cell 100A taken along line F4-F4 shown in FIG. 2.

FIG. 5 is an enlarged plan view of area A1 shown in FIG. 2.

FIG. 6 is a flowchart illustrating a method of aligning busbar electrodes employing markers 200A to 200D according to the embodiment.

FIG. 7 is a schematic view of printer 300 used to print electrodes and markers according to the embodiment.

FIGS. 8A and 8B are views respectively illustrating a front surface and a rear surface of transparent member 110T according to the embodiment.

FIG. 9 is a view illustrating an example of the positional offset of marker 200B and marker 200C according to the embodiment.

FIGS. 10A and 10B are views illustrating busbar electrodes according to modified examples.

### DETAILED DESCRIPTION OF EMBODIMENTS

Embodiments of the invention are explained with referring to drawings. In the respective drawings referenced herein, the same constituents are designated by the same reference numerals and duplicate explanation concerning the same constituents is basically omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### (1) General Configuration of Solar-Cell Module

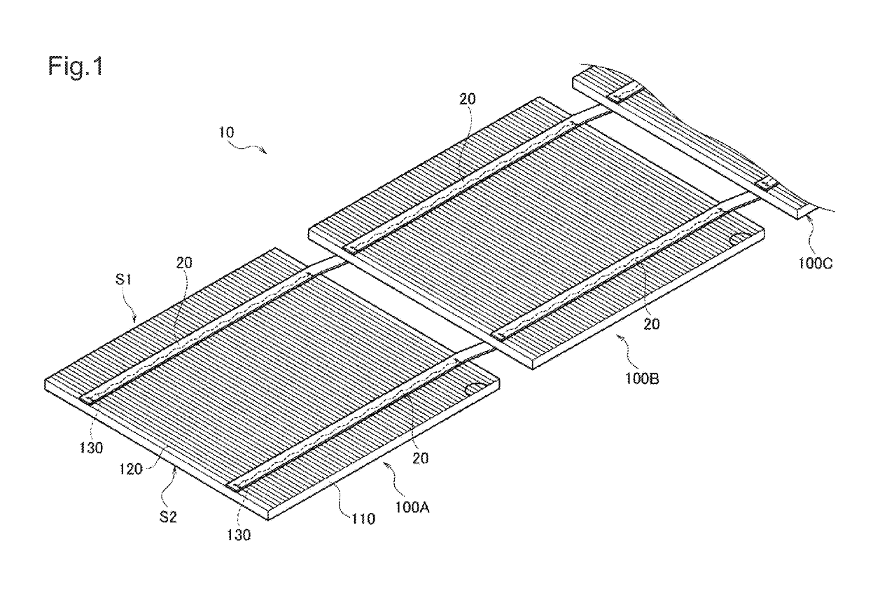

FIG. 1 is a schematic perspective view of a solar-cell module. As FIG. 1 shows, solar-cell module 10 includes plural solar cells (solar cells 100A to 100C). Note that the number of the solar cells included in solar-cell module 10 is not limited to the number shown in FIG. 1.

Each of tabs 20 electrically connects plural solar cells to one another. In the embodiment, tabs 20 are wiring materials. In the embodiment, each tab 20 is connected both to light-receiving surface S1 of solar cell 100A and to rear surface S2 of solar-cell 100B, which is a different solar cell that is adjacent to solar cell 100A, solar cells 100A and 100B being included in solar-cell module 10.

Tabs 20 are preferably made of a material with low electrical resistance, such as a thin plate-shaped copper, silver, gold, tin, nickel, aluminum, an alloy of these, or the like. Note that the front surface of each tab 20 may be plated with a conductive material such as a lead-free solder (e.g. SnAg_{3.0}Cu_{0.5}).

Solar-cells 100A to 100C may have the same structure, and therefore the structure of solar cell 100A is described below.

Solar cell 100A includes photoelectric conversion body 110, finger electrodes 120, and busbar electrodes 130.

Photoelectric conversion body 110 includes light-receiving surface S1 and rear surface S2. Light-receiving surface S1 (first surface) is a surface that is irradiated with light, such as sunlight. Rear surface S2 (second surface) is located on the opposite side to light-receiving surface S1. Photoelectric conversion body 110 generates carriers by irradiation of light onto light-receiving surface S1. Here, the carriers refer to the holes and electrons generated when light, such as sunlight, is absorbed by photoelectric conversion body 110.

Each finger electrode 120 collects the carriers generated by photoelectric conversion body 110. Plural finger electrodes 120 are provided on light-receiving surface S1.

Each busbar electrode 130 is electrically connected to plural finger electrodes 120 that are provided on light-receiving surface S1. In this embodiment, the width of each busbar electrode 130 is substantially the same as that of the finger electrodes 120 provided on light-receiving surface S1, and two busbar electrodes 130 are provided in parallel to each other on light-receiving surface S1. Each busbar electrode 130 is provided on light-receiving surface S1 so as to intersect plural finger electrodes 120.

Note that, though not shown in FIG. 1, rear surface S2 is provided with electrodes that are similar to both finger electrodes 120 and busbar electrode 130 (i.e., finger electrodes 220 and busbar electrodes 230 (see FIG. 3)).

Tabs 20 are wider than finger electrodes 120, 220, busbar electrode 130, and 230. Tabs 20 are bonded to the tops of busbar electrodes 130, light-receiving surface S1 of photoelectric conversion body 110, and to the tops of busbar electrodes 230, rear surface S2 of photoelectric conversion body 110 with a resin adhesive (not illustrated). In addition, solar-cell module 10 is provided with a light-receiving surface member, a rear surface member, and a sealing material to seal solar cells 100A to 100C that are connected to each other with tabs 20, but the configurations of and materials of these additional members are similar to those in the conventional case, so that no description of these members is given.

### (2) Configuration of Solar Cell

Subsequently, the configuration of solar cell 100A is described. Specifically, description is given of the overall configuration of solar cell 100A, and of the positions and shapes of busbar electrodes.

### (2.1) Overall Configuration

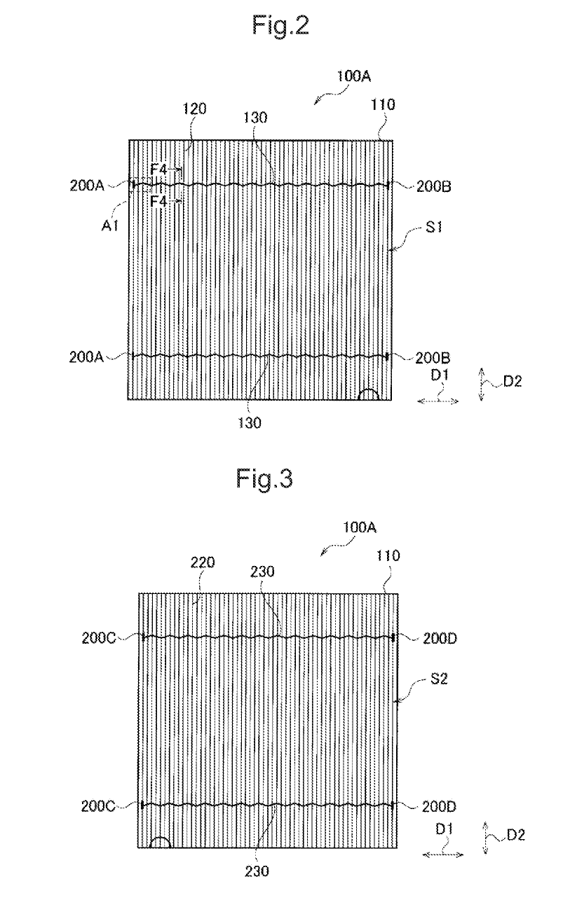

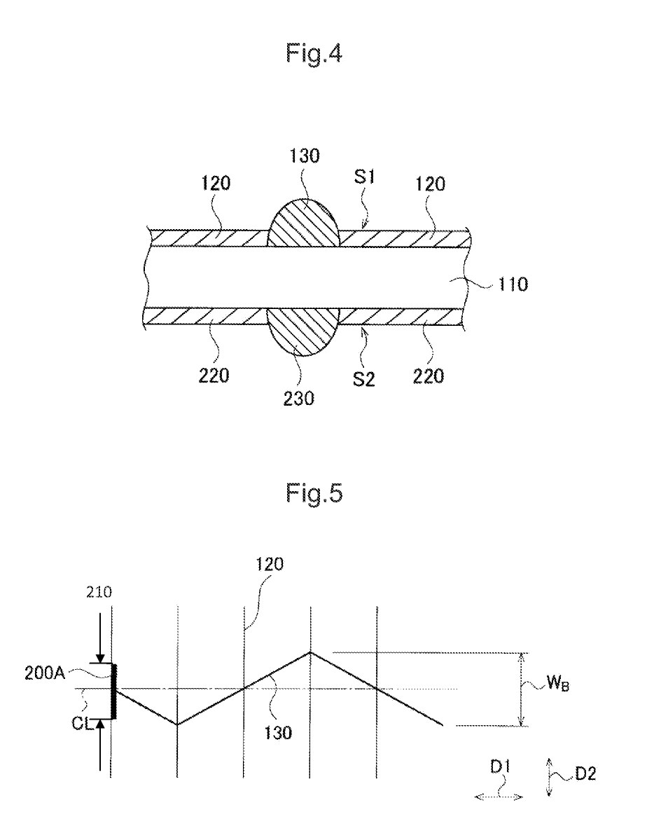

FIG. 2 is a plan view of light-receiving surface S1 of solar cell 100A. FIG. 3 is a plan view of rear surface S2 of solar cell 100A. FIG. 4 is a sectional view of a part of solar cell 100A taken along line F4-F4 shown in FIG. 2. Note that the hatching of photoelectric conversion body 110 is omitted from FIG. 4.

As has been described earlier, photoelectric conversion body 110 generates carriers by receiving light. For example, photoelectric conversion body 110 includes an n type region and a p type region inside of photoelectric conversion body 110. A semiconductor junction is formed at the interface of the n type region and the p type region. Photoelectric conversion body 110 may be formed with a semiconductor substrate made, for example, of a crystalline semiconductor material, such as mono crystal S1 and poly crystal S1, of a compound semiconductor material, such as GaAs and InP, or the like. Note that photoelectric conversion body 110 may have a so-called HIT (Hetero-junction with Intrinsic Thin layer) structure, which is a structure to improve the properties at the hetero-junction interface by sandwiching an intrinsic amorphous silicon layer between mono crystal silicon and amorphous silicon.

Light-receiving surface S1 of solar cell 100A is provided with finger electrodes 120 and busbar electrodes 130 that are connected to finger electrodes 120. Likewise, rear surface S2 of solar cell 100A is provided with finger electrodes 220 and busbar electrodes 230 that are connected to finger electrodes 220. Each busbar electrode 130 (230) extends in an orthogonal direction (in direction. D1) that is orthogonal to finger electrodes 120 (220).

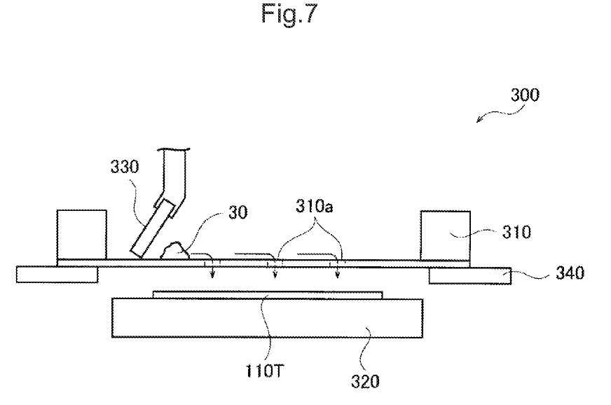

Finger electrodes 120 and 220 as well as busbar electrodes 130 and 230 may be formed by printing conductive paste 30 (not illustrated in FIG. 2 to FIG. 4; see FIG. 7) by screen printing or the like method.

As FIG. 2 and FIG. 3 show, each finger electrode 120 has a linear shape. In contrast, none of busbar electrodes 130 and busbar electrodes 230 has a linear shape. Specifically, each of busbar electrodes 130 and busbar electrodes 230 has a zigzag shape with a certain amplitude in the direction in which each finger electrode 120 (220) extends (in direction D2 shown in FIGS. 2 and 3).

In the embodiment, each busbar electrode 130 and each busbar electrode 230 have identical shapes. To put it differently, solar 11 100A includes busbar electrodes of identical shapes provided both on light-receiving surface S1 and on rear surface S2. In addition, busbar electrodes 230 are provided on rear surface 82 at the same positions where busbar electrodes 130 are formed on light-receiving surface S1 with photoelectric conversion body 110 located in between. To put it differently, in a plan view of photoelectric conversion body 110, the positions where busbar electrodes 130 are provided overlap the positions where busbar electrodes 230 are provided.

In addition, each of busbar electrodes 130 and busbar electrodes 230 is covered at least partially with tab 20. The resin adhesive to be used when busbar electrodes 130 (230) and tabs 20 are bonded together is preferably one that is hardened at a temperature lower than or equal to the melting point (approximately 200° C.) of the lead-free solder. Some of the adhesives to be used as the resin adhesive are thermo-setting resin adhesives such as an acrylic resin and highly-flexible polyurethane-based resin, as well as two-liquid reaction adhesives such as ones made by mixing a hardening agent with any of an epoxy resin, acrylic resin, and urethane resin. In addition, in this embodiment, the resin adhesive contains plural conducting particles. Nickel, nickel coated with gold, or the like may be used as such conducting particles.

Each busbar electrode 130 includes markers 200A and 200B. Likewise, each busbar electrode 230 includes markers 200C and 200D. To put it differently, in this embodiment, each of busbar electrodes 130 and busbar electrodes 230 includes two markers for alignment.

Markers 200A to 200D can be used to align busbar electrodes 130 provided on light-receiving surface S1 with busbar electrodes 230 provided on rear surface S2. Specifically, markers 200A to 200D are used to check whether the positions of busbar electrodes 130 are or are not properly aligned with the positions of busbar electrodes 230 in a plan view of photoelectric conversion body 110. Note that the specific method of the alignment is described later.

Both marker 200A and marker 200B are provided on light-receiving surface S1. Specifically, marker 200A and marker 200B are provided respectively at the two end portions of each busbar electrode 130 in the direction in which busbar electrode 130 extends (in direction D1 in FIGS. 2 and 3). Likewise, marker 200C and marker 200D are provided respectively at the two end portions of each busbar electrode 230 in the direction in which busbar electrode 230 extends (in direction D1 in FIGS. 2 and 3).

Markers 200A (200B) provided on light-receiving surface S1 overlap respectively markers 200D (200C) provided on rear surface S2 in a plan view of photoelectric conversion body 110. To put it differently, if light-receiving surface S1 faces upwards, markers 200D (200C) are positioned right below their corresponding markers 200A (200B) with photoelectric conversion body 110 located in between.

In addition, in this embodiment, markers 200A to 200D are provided at positions covered with tabs 20. To put it differently, after tabs 20 are bonded to photoelectric conversion body 110, neither markers 200A nor markers 200B (neither markers 200C nor markers 200D) are basically exposed from light-receiving surface S1 (rear surface S2).

### (2.2) Positions and Shapes of Busbar Electrodes

FIG. 5 is an enlarged plan view of area A1 shown in FIG. 2. As FIG. 5 shows, marker 200A is provided at an end portion of each busbar electrode 130 in the direction in which busbar electrode 130 extends (in direction D1 in FIG. 5). To put it differently, each marker 200A is continuous to the corresponding busbar electrode 130. In addition, each marker 200A is provided on center line CL passing on the center of the corresponding busbar electrode 130 in the direction orthogonal to the direction in which each busbar electrode 130 extends (in direction D2 in FIG. 5).

In this embodiment, each marker 200A has a rectangular shape. To put it differently, each of markers 200A to 200D has a shape that is different from each of non-linearly shaped busbar electrodes 130 and 230. Specifically, each marker 200A has a rectangular shape, and long side 210 of each marker 200A extends in the direction in which each finger electrode 120 extends (in direction D1). In addition, each marker 200A overlaps any of finger electrodes 120.

In this embodiment, each finger electrode 120 has a line width of approximately 0.1 mm. The pitch of finger electrodes 120 is approximately 2.0 mm. In addition, each busbar electrode 130 (230) has amplitude W_{B} of approximately 1.6 mm. In addition, the length of long side 210 of each of markers 200A to 200D is preferably smaller than amplitude W_{B}. However, to facilitate the alignment, the length of longer side 210 is preferably as large as possible. In addition, to avoid the exposure of markers 200A to 200D from light-receiving surface S1 after the completion of solar-cell module 10, the length of long side 210 is preferably smaller than the width of each tab 20.

Note that each marker 200B provided at the opposite end of the corresponding busbar electrode 130 to the corresponding marker 200A has a similar relative position and a similar shape to those of marker 200A. In addition, each marker 200C (see FIG. 3) provided at one end portion of the corresponding busbar electrode 230 is similar to each marker 200A whereas each marker 200D (see FIG. 3) provided at the other end portion of the corresponding busbar electrode 230 is similar to each marker 200B.

### (3) Method of Aligning Busbar Electrodes

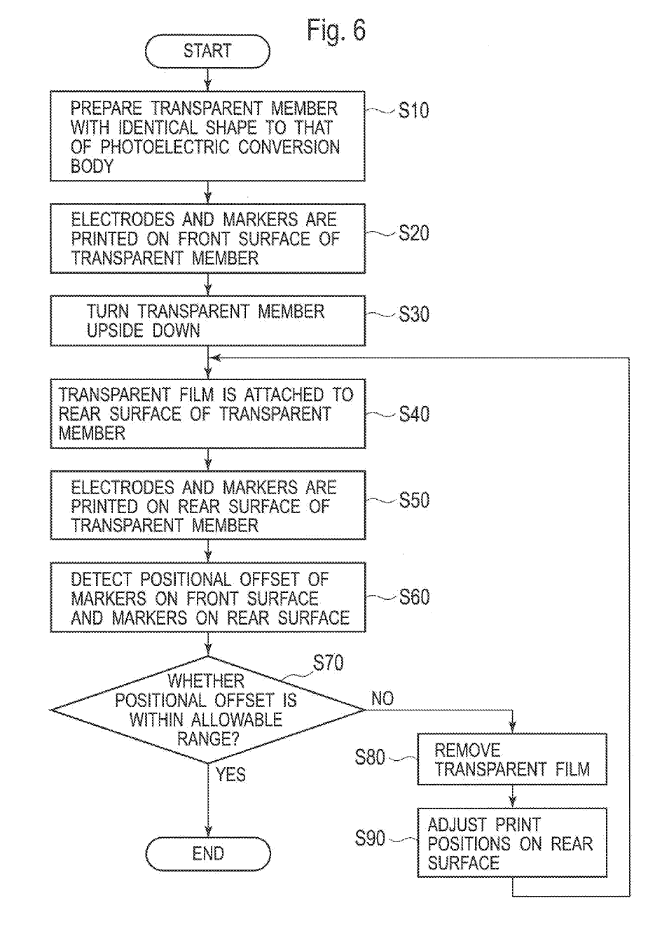

FIG. 6 is a flowchart illustrating a method of aligning busbar electrodes using above-described markers 200A to 200D. Specifically, FIG. 6 shows an operational flow to align the positions of busbar electrodes 130 provided on light-receiving surface S1 with the positions of busbar electrodes 230 provided on rear surface S2.

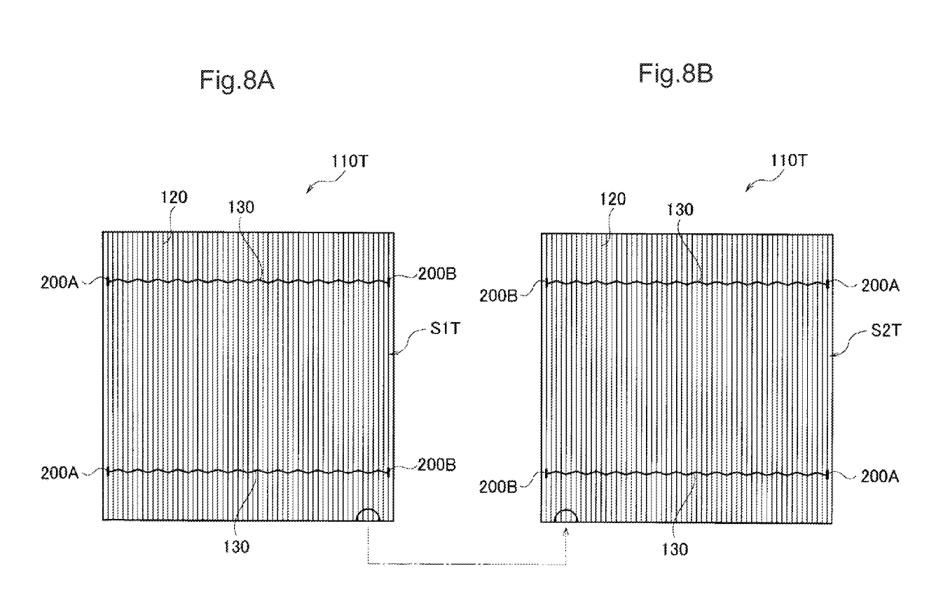

As FIG. 6 shows, at step S10, transparent member 110T (see FIG. 8) with an identical shape to that of photoelectric conversion body 110, that is, with the same quadrangular shape of the same size as that of photoelectric conversion body 110 is prepared. Transparent member 110T has certain transparency. Specifically, transparent member 110T needs to have enough transparency to allow the view from front surface S1T side to rear surface S2T side of transparent member 110T.

At step S20, electrodes and markers are printed on front surface SIT of transparent member 110T.

FIG. 7 is a schematic view of printer 300 to be used to print electrodes and markers. As FIG. 7 shows, printer 300 includes screen 310, stage 320, squeegee 330 and alignment mechanism 340.

Holes 310a are formed in screen 310 so as to correspond to the pattern of electrodes and markers. Transparent member 110T is mounted on stage 320. Note that in an actual printing process, photoelectric conversion body 110 is mounted on stage 320 in place of transparent member 110T. Stage 320 provides a function to adjust the position of transparent member 110T on the plane of screen 310.

Squeegee 330 pushes conductive paste 30 out through holes 310a formed in screen 310. Thus, conductive paste 30 is placed on transparent member 110T following the pattern of electrodes and markers.

Alignment mechanism 340 provides adjustment the position of screen 310 on the plane of transparent member 110T.

FIG. 8A shows a state where electrodes and markers are formed on front surface SIT of transparent member 110T. Using printer 300 shown in FIG. 7, finger electrodes 120 and busbar electrodes 130 are formed on front surface S1T of transparent member 110T. In addition, markers 200A and markers 200B to be used to align busbar electrodes 130 with busbar electrodes 230 are also formed along with finger electrodes 120 and busbar electrodes 130.

Subsequently, as FIG. 6 shows, at step S30, transparent member 110T is turned upside down to make rear surface S2T of transparent member 110T face upwards. Note that transparent member 110T is turned upside down in the direction orthogonal to the direction in which the squeegee 330 moves. FIG. 8B shows a state where transparent member 110T with electrodes and markers formed on front surface SIT is turned upside down.

At step S40, a transparent film is attached to rear surface S2T of transparent member 110T. Transparent film tray be anything that conductive paste 30 can be printed on.

At step S50, electrodes and markers are printed on rear surface S2T of transparent member 110T. The printing of electrodes and markers on rear surface S2T is performed using another printer that is similar to printer 300 shown in FIG. 7. Alternatively, if the positions of stage 320 and alignment mechanism 340 can be stored in a memory, the same printer may be used. In addition, the printing of electrodes and markers on rear surface S2T is performed using markers 200A and 200B formed on front surface SIT as the reference.

At step S60, on the basis of the positions of markers 200A and 200B formed on front surface SIT and the positions of markers 200C and 200D formed on rear surface S2T, the positional offset of busbar electrodes 130 formed on front surface SIT and busbar electrodes 230 formed on rear surface S2T is detected.

The positional offset can be detected using a detection system equipped with a camera and the like. Alternatively, the positional offset may be visually detected by an operator if the pitch of the electrodes and the sizes of the markers allow it.

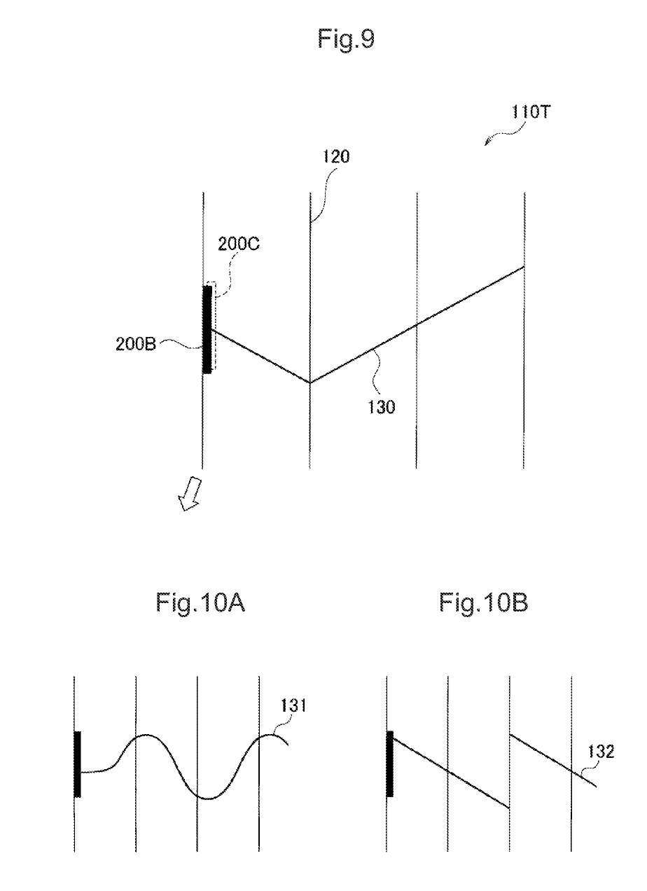

FIG. 9 is a view illustrating an example of the positional offset of marker 200B and marker 200C. As FIG. 9 shows, in the state where transparent member 110T is turned upside down (see FIG. 8B), marker 200E formed on front surface SIT is positioned at the left end portion of transparent member 110T. If, in this state, electrodes and markers are printed on rear surface S2T of transparent member 110T, marker 200B completely overlaps marker 200C unless the positional offset in printing occurs.

In contrast, if the positional offset in printing occurs, marker 200B does not completely overlap marker 200C as FIG. 9 shows. In this way, by checking the positions of marker 200B and marker 200C printed on transparent member 110T, whether or not the positional offset is beyond an allowable range.

At step S70, whether or not the positional offset is beyond an allowable range is determined. If the positional offset is within the allowable range (YES at step S70), the operation is completed.

In contrast, if the positional offset is beyond the allowable range (NO at step S70), the transparent film attached to rear surface S2T of transparent member 110T is removed at step S80.

At step S90, the positions of the electrodes and markers printed on rear surface S2T are adjusted. Specifically, by adjusting either stage 320 or alignment mechanism 340 of printer 300, the positions of the electrodes and markers printed on rear surface S2T are adjusted. By adjusting the position of stage 320, the position of transparent member 110T mounted on stage 320 relative to screen 310 is changed. In contrast, by adjusting the position of screen 310, the position of screen 310 relative to transparent member 110T is changed.

In the example shown in FIG. 9, by adjusting either stage 320 or alignment mechanism 340, the positions at which the electrodes and markers are printed are moved in the direction indicated by the arrow in FIG. 9.

Subsequently, the processes of steps S40 to S90 are repeated. Specifically, if the positional offset is beyond the allowable range, the printing on rear surface S2T is performed again. Note that, needless to say, the operational flow described above can be automated with a system.

### (4) Advantageous Effects

According to above-described solar cell 100A (100B or 100C) and the above-described method of aligning busbar electrodes, the positions of busbar electrodes 130 formed on light-receiving surface S1 can be easily aligned with the positions of busbar electrodes 230 formed on rear surface S2.

Accordingly, even if the areas where busbar electrodes 130 are arranged are pressurized when busbar electrodes 130 (230) and tabs 20 are bonded together, no unsupportable shear stress acts on photoelectric conversion body 110 because the positions of busbar electrodes 130 are aligned with the positions of busbar electrodes 230. Specifically, the stress acting on photoelectric conversion body 110 via busbar electrodes 130 at the time of pressurization is borne by busbar electrodes 230, so that no unsupportable shear stress acts on photoelectric conversion body 110.

According to this embodiment, occurrence of damages such as cracks in photoelectric conversion body 110 can be reduced and the lowering of yields of solar cells can be reduced.

According to this embodiment, each of markers 200A to 200D is provided on center line CL of the corresponding busbar electrode (see FIG. 5). Accordingly, the shapes of the markers and of the busbar electrodes can be used for alignment of positions, so that the workability and accuracy of the alignment of positions can be improved.

In this embodiment, markers 200A (200B) formed on light-receiving surface S1 overlap respectively markers 200D (200C) formed on rear surface 82 in a plan view of photoelectric conversion body 110. Accordingly, such a configuration is convenient when the aligning is performed with transparent member 110′ turned upside down.

In this embodiment, each of markers 200A to 200D has a rectangular shape. Specifically, each of markers 200A to 200D has a box shape, and long side 210 extends in the direction in which each finger electrode extends (in direction D2). In addition, each of markers 200A to 200D overlaps one of finger electrodes. Accordingly, the shapes of the markers and of finger electrodes can be used for alignment of positions, so that the workability and accuracy of the alignment of positions can be improved furthermore.

In this embodiment, markers 200A to 200D are provided at positions that are covered with tabs 20. Accordingly, if solar-cell module 10 is completed, none of markers 200A to 200D is basically exposed from light-receiving surface 81, and even if markers 200A to 200D are provided, the conversion efficiency of solar cells does not deteriorate.

### (5) Other Embodiments

As described above, the content of the invention is disclosed by means of the embodiment, but the descriptions and the drawings that form a part of this disclosure should not be understood as anything that limits the invention. Those skilled in the art may conceive of various alternative embodiments, examples, and techniques from this disclosure.

For example, in the above-described embodiment, markers 200A to 200D are provided at positions that are covered with tabs 20, but markers 200A to 200D do not necessarily have to be provided at positions that are covered with tabs 20.

In addition, each of markers 200A to 200D may have a circular shape or a triangular shape instead of a rectangular shape. In addition, the positions of and the number of the markers on light-receiving surface S1 (rear surface S2) are not limited to those in the above-described embodiment. For example, two markers only need to be provided respectively at two positions (e.g., marker 200A located at the upper left in FIG. 2 and marker 200B located at the lower right) on a diagonal line on light-receiving surface S1 (rear surface S2). Alternatively, if at least two markers are provided on each of light-receiving surface S1 and rear surface S2, the positions thereof do not have to be on a diagonal line. In addition, markers do not have to be continuous to busbar electrodes, and may be provided near but independently of the busbar electrodes.

In addition, the shapes of the markers provided on light-receiving surface S1 may be different from the shapes of the markers provided on rear surface S2. For example, each of the markers on light-receiving surface S1 may have a rectangular shape, whereas each of the markers on rear surface S2 may have a triangular shape. If the markers have different shapes in this way, the n side and the p side of photoelectric conversion body 110 can be distinguished from each other easily.

In the above-described embodiment, each busbar electrode has a zigzag shape, but the invention is applicable to a case where each of busbar electrodes has a non-linear shape such as a wavy shape as busbar electrode131 shown in FIG. 10A or an oblique-line shape as busbar electrodel32 shown in FIG. 10B. In addition, the shape of each busbar electrode provided on light-receiving surface S1 may be partly different a little from the shape of each busbar electrode provided on rear surface S2.

In the above-described embodiment, the number of finger electrodes 120 provided on light-receiving surface S1 of solar cell 100A and the number of finger electrodes 220 provided on rear surface 52 of solar cell 100A are equal to each other, but may be different from each other. Specifically, the number of finger electrodes 220 may be larger than the number of finger electrodes 120.

In the above-described embodiment, a resin adhesive that contains conducting particles is used, but the resin adhesive does not necessarily have to contain conducting particles.

According to the embodiments of the invention, the solar-cell module and the solar cell that can be provided are capable of reducing the lowering of yields caused by the damages on the photoelectric conversion body at the time of the manufacturing of the solar-cell nodule and of the solar cell when busbar electrodes with non-linear shapes such as zigzag shapes are provided.

What is claimed is:

1. A solar-cell module comprising:
a plurality of solar cells electrically connected to each other by wiring materials, each solar cell comprising:
a photoelectric conversion body including a first surface irradiated with light and a second surface located on the opposite side to the first surface, the photoelectric conversion body configured to generate carriers by the irradiation of light;
a plurality of finger electrodes provided on both the first surface and the second surface, and configured to collect the carriers generated by the photoelectric conversion body; and
a busbar electrode provided on each of the first surface and the second surface so as to intersect the plurality of finger electrodes, and having a non-linear shape, wherein
each of the busbar electrodes provided on the first surface and the busbar electrode formed on the second surface includes at least two markers for alignment of positions.

2. The solar-cell module of claim 1, wherein each of the markers is provided on a center line that passes through a center of the corresponding busbar electrode a direction orthogonal to a direction in which the busbar electrode extends.

3. The solar-cell module of claim 1, wherein, in a plan view of the photoelectric conversion body, each of the markers provided on the first surface overlaps the corresponding marker provided on the second surface.

4. The solar-cell module of claim 1, wherein
each of the markers has a rectangular shape, and
each of the markers has a long side extending in a direction in which each of the plurality of finger electrodes extends.

5. The solar-cell module of claim 1, wherein the markers provided on the first surface are different in shape from the markers provided on the second surface.

6. The solar-cell module of claim 1, wherein the wiring materials are bonded to tops of the busbar electrodes with a resin adhesive.

7. A solar cell comprising:
a photoelectric conversion body including a first surface irradiated with light and a second surface located on the opposite side to the first surface, the photoelectric conversion body configured to generate carriers by the irradiation of light;
a plurality of finger electrodes provided on both the first surface and the second surface, and configured to collect the carriers generated by the photoelectric conversion body; and
a busbar electrode provided on each of the first surface and the second surface so as to intersect the plurality of finger electrodes, and having a non-linear shape, wherein
each of the busbar electrodes provided on the first surface and the busbar electrode formed on the second surface includes at least two markers for alignment of positions.

8. The solar cell of claim 7, wherein each of the markers is provided on a center line that passes through a center of the corresponding busbar electrode in a direction orthogonal to a direction in which the busbar electrode extends.

9. The solar cell of claim 7, wherein, in a plan view of the photoelectric conversion body, each of the markers provided on the first surface overlaps the corresponding marker provided on the second surface.

10. The solar cell of claim 7, wherein
each of the markers has a rectangular shape, and
each of the markers has a long side extending in a direction in which each of the plurality of finger electrodes extends.

11. The solar cell of claim 7, wherein the markers provided on the first surface are different in shape from the markers provided on the second surface.

12. A method of producing a solar cell comprising:
forming a photoelectric conversion body including a first surface irradiated with light and a second surface located on the opposite side to the first surface, the photoelectric conversion body configured to generate carriers by the irradiation of light;
forming a plurality of finger electrodes provided on both the first surface and the second surface, and configured to collect the carriers generated by the photoelectric conversion body; and
forming a busbar electrode provided on each of the first surface and the second surface so as to intersect the plurality of finger electrodes, wherein each of the busbar electrodes provided on the first surface and the busbar electrode formed on the second surface includes at least two markers for alignment of positions.
